(19) United States
(12) Patent Application Publication
(10) Pub. No.: US 2018/0198066 A1
(43) Pub. Date: Jul. 12, 2018

(54) MASK PLATES AND METHODS FOR ASSEMBLING THE SAME

(71) Applicants: BOE TECHNOLOGY GROUP CO., LTD., Beijing (CN); Ordos Yuansheng Optoelectronics Co., Ltd., Ordos (CN)

(72) Inventors: Zhiming Lin, Beijing (CN); Zhen Wang, Beijing (CN)

(21) Appl. No.: 15/685,881

(22) Filed: Aug. 24, 2017

(30) Foreign Application Priority Data
Jan. 9, 2017 (CN) 201710015371.0

(51) Int. Cl. H01L 51/00; H01L 27/32; C23C 14/06; C23C 14/04

(52) U.S. Cl. CPC H01L 51/0011; C23C 14/042; C23C 14/06; H01L 27/3211

(57) ABSTRACT

The embodiments of the present disclosure provide a mask plate and a method for assembling a mask plate. The mask sheet comprises a frame; a howling sheet located on the frame; and at least one mask sheet fixed onto the frame and supported by the howling sheet, wherein the at least one mask sheet is fixed onto the howling sheet via at least one welding part.

### CROSS-REFERENCE TO RELATED APPLICATION(S)

This application claims priority to the Chinese Patent Application No. 201710015371.0, filed on Jan. 9, 2017, which is incorporated herein by reference in its entirety.

### TECHNICAL FIELD

The embodiments of the present disclosure relate to a mask plate and a method for assembling the same.

### BACKGROUND

Organic Light Emitting Diode (OLED) displays are self-luminous display apparatuses. In the process of manufacturing an OLED display, a mask sheet (for example, including a Fine Metal Mask (FMM)) sheet is used as an evaporation mask to form an evaporated pattern on a substrate.

However, in the conventional manufacturing process, Pixel Position Accuracy (PPA) at each position on the substrate cannot be corrected.

### SUMMARY

At least one embodiment of the present disclosure provides a mask plate and a method for assembling a mask plate to correct pixel position accuracy at a corresponding position on a substrate.

According to an aspect of the present disclosure, there is proposed a mask plate, comprising:

a frame;

a howling sheet located on the frame; and

at least one mask sheet fixed onto the frame and supported by the howling sheet,

wherein the at least one mask sheet is fixed onto the howling sheet via at least one welding part.

In an embodiment, the at least one welding part comprises a plurality of welding parts, and the plurality of welding parts are located in end portions of an overlapped region between the mask sheet and the howling sheet in an extension direction of the howling sheet.

In an embodiment, there are equal number of welding parts in both end portions of the overlapped region.

In an embodiment, there are different numbers of welding parts in both end portions of the overlapped region.

In an embodiment, the at least one welding part is located in the same end portions of the overlapped region.

In an embodiment, the mask sheet has recessed areas formed by etching, and the welding parts are formed on the recessed areas.

According to another aspect of the present disclosure, there is proposed a method for assembling a mask plate comprising a frame, a howling sheet and at least one mask sheet, the method comprising:

fixing both ends of the howling sheet onto the frame;

fixing the mask sheet onto the frame; and

fixing the at least one mask sheet onto the howling sheet via at least one welding part.

In an embodiment, the method further comprises: forming at least one recessed area for forming the welding parts on the mask sheet by etching.

In an embodiment, the method further comprises:

measuring Pixel Position Accuracy (PPA) of each of a plurality of predetermined pixel points; and

determining an arrangement scheme of the welding parts according to the measured PPA.

In an embodiment, determining an arrangement scheme of the welding parts according to the measured PPA comprises: determining a number of the welding parts and which end portions of an overlapped region between the mask sheet and the howling sheet the welding parts are to be located in an extension direction of the howling sheet according to the measured PPA.

In an embodiment, determining an arrangement scheme of the welding parts according to the measured PPA further comprises: determining positions of the welding parts in the end portions of the overlapped region and/or welding energies for the welding parts.

According to the embodiments of the present disclosure, at least one mask sheet is fixed onto a howling sheet via at least one welding part. By setting at least one of a number of the welding parts, positions of the welding parts, and corresponding welding energies for the welding parts, PPA in various variation trends can be corrected according to practical requirements, thereby improving the yield rate of the mask plate.

### BRIEF DESCRIPTION OF THE DRAWINGS

In order to more clearly illustrate the technical solutions according to the embodiments of the present disclosure, the accompanying drawings, which are intended to be used in the description of the embodiments, will be briefly described below. It will be apparent that the accompanying drawings described in the following description are merely some embodiments of the present disclosure. Those skilled in the art can obtain other accompanying drawings according to these accompanying drawings without contributing any creative work, wherein in the accompanying drawings:

FIG. 1 illustrates a schematic plan view of a mask plate;

FIGS. 2A to 2C illustrate exemplary diagrams of three PPA variation trends, respectively;

FIG. 3 illustrates a schematic plan view of a mask plate according to an embodiment of the present disclosure;

FIG. 4 illustrates a schematic plan view of a first exemplary arrangement of welding parts according to an embodiment of the present disclosure;

FIG. 5 illustrates a schematic plan view of a second exemplary arrangement of welding parts according to an embodiment of the present disclosure;

FIG. 6 illustrates a schematic plan view of a third exemplary arrangement of welding parts according to an embodiment of the present disclosure;

FIG. 7 illustrates a schematic plan view of pixel points to be checked according to an embodiment of the present disclosure;

FIG. 8 illustrates a schematic comparison diagram of PPA in the arrangement of the welding parts shown in FIG. 4 according to an embodiment of the present disclosure;

FIGS. 9A and 9B illustrate schematic comparison diagrams of PPA in the arrangement of the welding parts shown in FIG. 5 according to an embodiment of the present disclosure respectively;

FIGS. 10A and 10B illustrate schematic comparison diagrams of PPA in the arrangement of the welding parts shown in FIG. 4 according to an embodiment of the present disclosure;

FIGS. 11A to 11C illustrate schematic plan views of positions of welding parts according to an embodiment of the present disclosure;

FIG. 12 illustrates a schematic plan view of positions of recessed areas according to an embodiment of the present disclosure; and

FIG. 13 illustrates a flowchart of a method for assembling a mask plate according to an embodiment of the present disclosure.

### DETAILED DESCRIPTION

In order to make the purposes, technical solutions and advantages of the embodiments of the present disclosure more clear, the technical solutions in the embodiments of the present disclosure will be clearly and completely described below in conjunction with the accompanying drawings in the embodiments of the present disclosure. Obviously, the embodiments described are a part of the embodiments of the present disclosure instead of all the embodiments. All other embodiments obtained by those of ordinary skill in the art based on the described embodiments of the present disclosure without contributing any creative work are within the protection scope of the present disclosure. It should be noted that throughout the accompanying drawings, the same elements are represented by the same or similar reference signs. In the following description, some specific embodiments are for illustrative purposes only and are not to be construed as limiting the present disclosure, but merely examples of the embodiments of the present disclosure. The conventional structure or construction will be omitted when it may cause confusion with the understanding of the present disclosure. It should be noted that shapes and dimensions of components in the figures do not reflect true sizes and proportions, but only illustrate contents of the embodiments of the present disclosure.

Unless otherwise defined, technical terms or scientific terms used in the embodiments of the present disclosure should be of ordinary meanings to those skilled in the art. “First”, “second” and similar words used in the embodiments of the present disclosure do not represent any order, quantity or importance, but are merely used to distinguish between different constituent parts.

In addition, in the accompanying drawings of the embodiments of the present disclosure, only the structures referred to in the embodiments of the present disclosure are concerned, and other structures may be referred to the conventional design. In addition, it will be understood that when an element such as a layer, a film, a region or a substrate etc. is referred to as being located “on” or “below” another element, the element may be “directly” located “on” or “below” the other element, or there may also be an intermediate element therebetween. In addition, “on” or “below” only represents a relative positional relationship, and the “on” or “below” relationship may change accordingly when the element or the entire device is turned over.

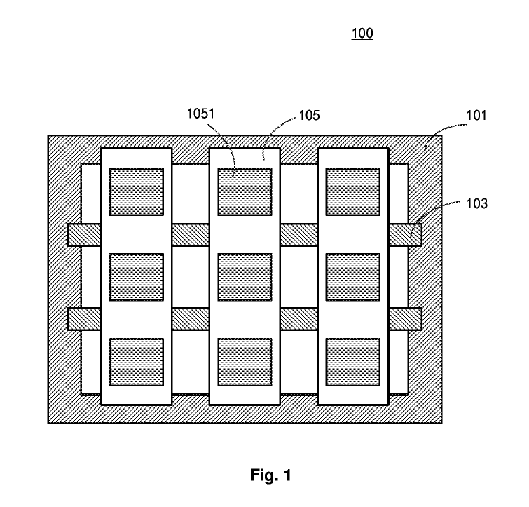

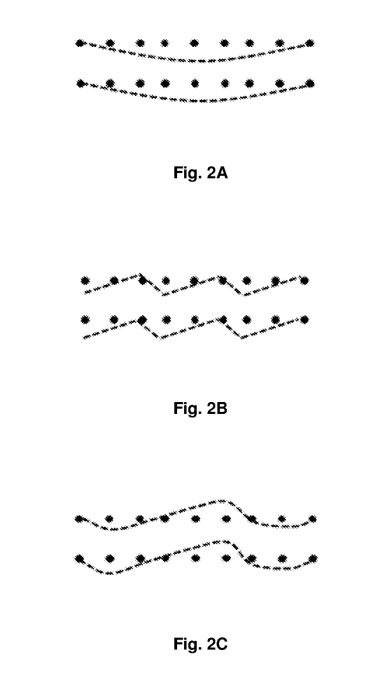

As shown in FIG. 1, a mask plate 100 may comprise a frame 101, a howling sheet 103 located on the frame 101, and at least one mask sheet 105 located on the frame 101. The mask sheet 105 may comprise a plurality of mask units 1051, which are portions having a deposited or evaporated pattern. For a plurality of pixel points in a pixel array on a substrate, Pixel Position Accuracy (PPA) needs to be corrected so that a PPA offset of each pixel point will be as small as possible. In practical applications, there will be a certain variation trend for the PPA. FIGS. 2A to 2C illustrate diagrams of three exemplary PPA variation trends respectively. In FIGS. 2A to 2C, circular black dots represent a plurality of pixel points to be checked in the pixel array, and each dotted line represents a PPA variation trend curve for each row of pixels. For example, a corresponding PPA variation trend curve may be obtained by calculating PPA of each pixel point for each row of pixels, obtaining coordinates of various offset points by taking a position of a corresponding pixel in a horizontal direction as a horizontal coordinate and corresponding PPA as a longitudinal coordinate, and obtaining a corresponding PPA variation trend curve by connecting all the offset points. In a practical process of manufacturing a mask plate, various PPA variation trend curves can be obtained due to various reasons. FIG. 2A illustrates an exemplary variation trend in a single arc shape, FIG. 2B illustrates an exemplary variation trend in an “N” shape, and FIG. 2C illustrates an exemplary variation trend in a multi-arc shape, for example, “W” or “M” shape. In the conventional process of manufacturing a mask sheet, there is no effective method for correcting PPA for various PPA variation trends.

The embodiments of the present disclosure provide a mask plate and a method for assembling a mask plate, which will be described in detail below with reference to the accompanying drawings.

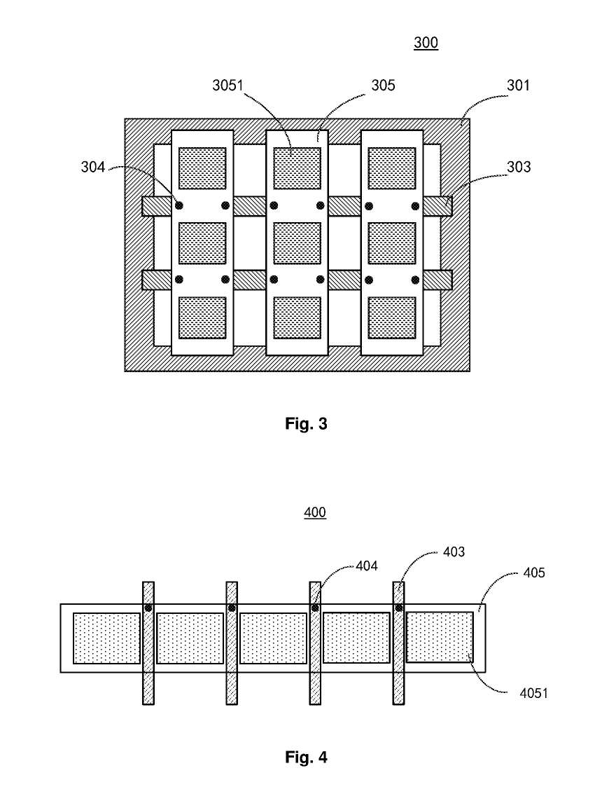

FIG. 3 illustrates a schematic plan view of a mask plate according to an embodiment of the present disclosure. As shown in FIG. 3, the mask plate 300 may comprise a frame 301; a howling sheet 303 located on the frame 301; and at least one mask sheet 305 fixed onto the frame 301 and supported by the howling sheet 303, wherein the at least one mask sheet 305 is fixed onto the howling sheet 303 via at least one welding part 304. The mask sheet 305 may comprise a plurality of mask unit 3051. In an embodiment, it can be seen from FIG. 3 that the at least one welding part 304 is located in an overlapped region between the mask sheet 305 and the howling sheet 303 (one mask sheet and one howling sheet will form one corresponding overlapped region) in an extension direction of the howling sheet 303. In a preferable embodiment, the at least one welding part 304 is located in end portions of the overlapped region (i.e., both end portions in the extension direction of the howling sheet 303). It is to be noted that the end portion here should be understood as a region closer to either of the two ends of the overlapped region than to the center of the overlapped region in the extension direction and should not be understood as being limited to only the end of the overlapped region.

The inventors of the present disclosure have found that, in the process of manufacturing an OLED display, when an evaporated pattern is formed on a substrate using an evaporation mask, the mask sheet may be slightly deformed, which is one of the reasons for changes of PPA for each pixel. In a structure of the conventional mask plate shown in FIG. 1, the howling sheet 103 is placed on the frame 101, the howling sheet 103 and the mask sheet 105 are fixed onto the frame 103 by welding, respectively, and there is no welding part between the howling sheet 103 and the mask sheet 105. As shown in FIG. 3, the embodiments of the present disclosure can correct undesirable PPA by fixing at least one mask sheet 305 onto the howling sheet 303 via at least one welding part 304.

In the example of FIG. 3, a plurality of welding parts 304 are provided for each mask sheet 305, and equal number of welding parts 304 are provided on opposite sides of the mask sheet 305 in the extension direction of the howling sheet 303. For each overlapped region, equal numbers of welding parts 304 are provided in both end portions of the overlapped region. It will be understood by those skilled in the art that this is only an exemplary implementation, and the embodiments of the present disclosure are not limited thereto. Further, in the example shown in FIG. 3, the arrangements of the welding parts 304 are the same for the plurality of mask sheets 305. It will be understood by those skilled in the art that this is only an exemplary implementation, and the arrangements of the welding parts 304 may be different for the plurality of mask sheets 305.

FIG. 4 illustrates a mask plate 400 according to another embodiment of the present disclosure, in which only one exemplary mask sheet 405 and a corresponding howling sheet 403 are shown, wherein at least one welding part 404 is located on the same side of the mask sheet 405 in an extension direction of the howling sheet 403. In other words, for each of overlapped regions corresponding to the mask sheet 405, the at least one welding part 404 is located in the same end portions of the overlapped region.

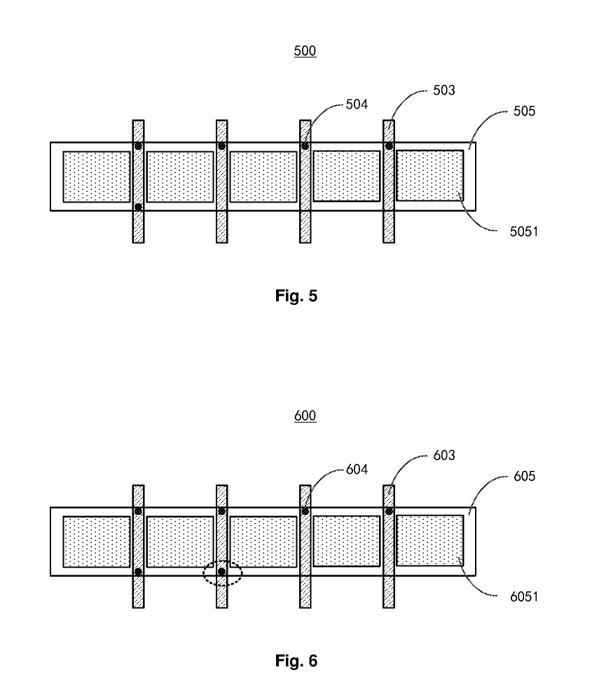

FIG. 5 illustrates a mask plate 500 according to another embodiment of the present disclosure, in which only one exemplary mask sheet 505 and a corresponding howling sheet 503 are shown, wherein a plurality of welding parts 504 are located on different sides of the mask sheet 505 in an extension direction of the howling sheet 503, and there are different numbers of welding parts on opposite sides of the mask sheet 505. In other words, in various overlapped regions corresponding to the mask sheets 505, there are different numbers of welding parts 504 in both end portions of at least one of the overlapped regions.

FIG. 6 illustrates a mask plate 600 according to another embodiment of the present disclosure, in which only one exemplary mask sheet 605 and a corresponding howling sheet 603 are shown, wherein a plurality of welding parts 604 are located on different sides of the mask sheet 605 in an extension direction of the howling sheet 603, and there are different numbers of welding parts 604 on opposite sides of the mask sheet 605. As compared with the mask plate 500 in FIG. 5, one additional welding part 604 (as indicated by the dashed block) has been added on the lower side of the mask sheet 605 in FIG. 6.

According to the embodiments of the present disclosure, PPA at a corresponding pixel position is corrected utilizing a solidification contraction trend in the welding process by welding between the mask sheet and the howling sheet. A relationship between different arrangements of the welding parts and correction results of PPA will be described in detail below. It should be noted that in the following description of the specification, “up”, “down”, “left”, and “right” only represent a relative positional relationship between corresponding structures in the accompanying drawings for convenience of description, and do not represent a positional relationship in the practical process flow.

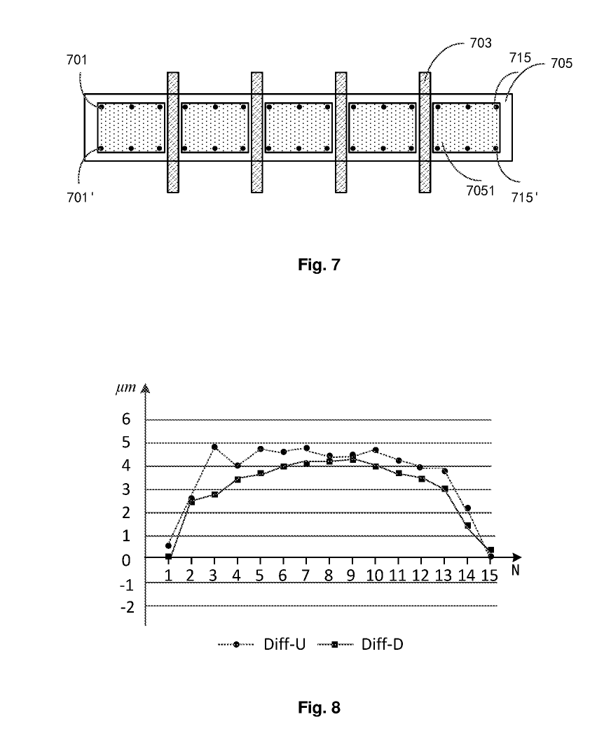

FIG. 7 illustrates a diagram of pixel points to be checked according to an embodiment of the present disclosure. As shown in FIG. 7, an exemplary mask sheet 705 comprises a plurality of mask units 7051, and 703 represents a howling sheet. Black dots 701 to 715 in FIG. 7 represent corresponding positions of 15 pixel points to be checked on the mask sheet 705, which are located on the upper side of the mask sheet 705. Black dots 701′ to 715′ represent corresponding positions of another 15 pixel points to be checked on the mask sheet 705, which are located on the lower side of the mask sheet 705. According to the embodiments of the present disclosure, PPA variation conditions of the 30 pixel points are checked respectively for the various exemplary arrangements of the welding parts shown in FIGS. 4 to 6 and PPA variation trends are shown in a curve form.

By taking the arrangement of the welding parts shown in FIG. 4 as an example, four welding parts 404 are located on the same side of the mask sheet 405. FIG. 8 illustrates a schematic comparison diagram of PPA in the arrangement of the welding parts shown in FIG. 4 according to an embodiment of the present disclosure. In FIG. 8, the horizontal axis represents 15 pixel points which are sequentially numbered in an order from left to right, where N=1, . . . , 15, and the vertical axis represents difference values in micrometers (μm) between PPA checked for various pixel points with the welding parts arranged as shown in FIG. 4 and PPA checked for corresponding pixel points without the welding parts, where solid circles represent difference value points obtained for the 15 pixel points 701-715 on the upper side of the mask sheet 705 in FIG. 7, and these difference value points are sequentially connected by dashed lines and represented as Diff-U; and solid squares represent difference value points which are obtained for the 15 pixel points 701′-715′ on the lower side of the mask sheet 705 in FIG. 7, and these difference value points are sequentially connected by solid lines and represented as Diff-D. As shown in FIG. 8, even if there is no welding part provided on the lower side of the mask sheet 705, and only the upper side of the mask sheet 705 has welding parts provided thereon, PPA of the pixel points on the lower side is also influenced.

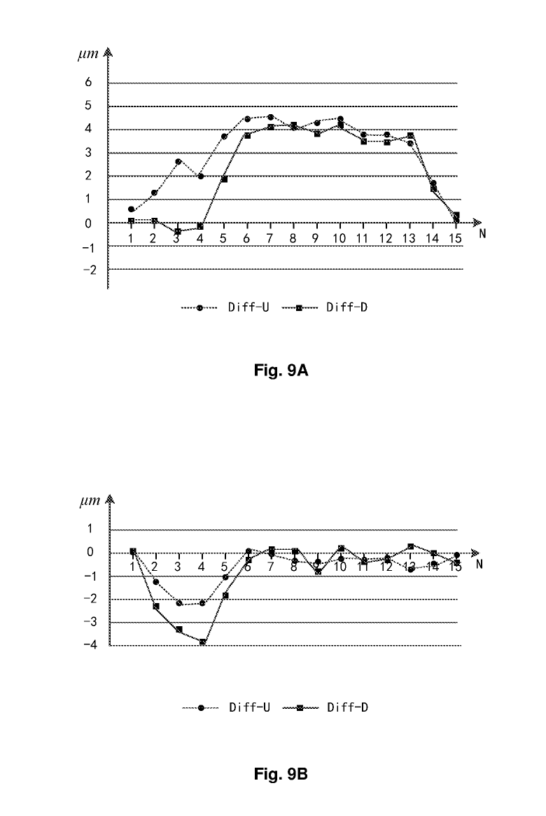

By taking the arrangement of the welding parts shown in FIG. 5 as an example, four welding parts 504 are located on one side of the mask sheet 505, and only one welding part is provided on the other side of the mask sheet 505. FIGS. 9A and 9B illustrate schematic comparison diagrams of PPA in the arrangement of the welding parts shown in FIG. 5 according to an embodiment of the present disclosure. Similarly to FIG. 8, in FIGS. 9A and 9B, the horizontal axis represents 15 pixel points which are sequentially numbered in an order from left to right, where N=1, . . . , 15, solid circles represent difference value points obtained for the 15 pixel points 701-715 on the upper side of the mask sheet 705 in FIG. 7, and these difference value points are sequentially connected by dashed lines and represented as Diff-U; and solid squares represent difference value points which are obtained for the 15 pixel points 701′-715′ on the lower side of the mask sheet 705 in FIG. 7, and these difference value points are sequentially connected by solid lines and represented as Diff-D.

In FIG. 9A, the vertical axis represents difference values in micrometers (μm) between PPA checked for various pixel points with the welding parts arranged as shown in FIG. 5 and PPA checked for corresponding pixel points without the welding parts. As shown in FIG. 9A, as compared with the curve shown in FIG. 8, for the pixel points 701′ to 705′ on the lower side, i.e., points where N=1, . . . , 5 of the Diff-D curve in the figure, the PPA variation trend slows down as one welding part is added on the lower left side of the mask sheet 505 in FIG. 5 as compared to the arrangement of the welding parts shown in FIG. 4. In FIG. 9B, the vertical axis represents difference values in micrometers (μm) between PPA checked for various pixel points with the welding parts arranged as shown in FIG. 5 and PPA checked for corresponding pixel points with the welding parts arranged as shown in FIG. 4. FIG. 9B more visually illustrates different influences on PPA for the arrangement of the welding parts shown in FIG. 5 and the arrangement of the welding parts shown in FIG. 4.

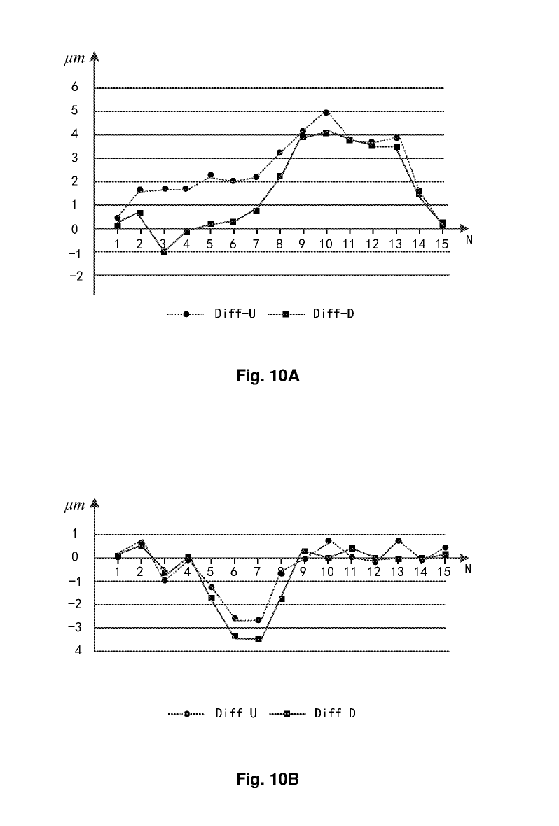

By taking the arrangement of the welding parts shown in FIG. 6 as an example, four welding parts 604 are located on one side of the mask sheet 605, and two welding parts are provided on the other side of the mask sheet 605. FIGS. 10A and 10B illustrate schematic comparison diagrams of PPA in the arrangement of the welding parts shown in FIG. 6 according to an embodiment of the present disclosure. Similarly to FIGS. 8, 9A and 9B, in FIGS. 10A and 10B, the horizontal axis represents 15 pixel points which are sequentially numbered in an order from left to right, where N=1, . . . , 15, solid circles represent difference value points obtained for the 15 pixel points 701-715 on the upper side of the mask sheet 705 in FIG. 7, and these difference value points are sequentially connected by dashed lines and represented as Diff-U; and solid squares represent difference value points which are obtained for the 15 pixel points 701′-715′ on the lower side of the mask sheet 705 in FIG. 7, and these difference value points are sequentially connected by solid lines and represented as Diff-D.

In FIG. 10A, the vertical axis represents difference values in micrometers (μm) between PPA checked for various pixel points with the welding parts arranged as shown in FIG. 6 and PPA checked for corresponding pixel points without the welding parts. As shown in FIG. 10A, as compared with the curve shown in FIG. 8, for the pixel points 701′ to 709′ on the lower side, i.e., points where N=1, . . . , 9 of the Diff-D curve in the figure, the PPA variation trend slows down as two welding parts are added on the lower left side of the mask sheet 605 in FIG. 6 as compared with the arrangement of the welding parts shown in FIG. 4. In FIG. 10B, the vertical axis represents difference values in micrometers (μm) between PPA checked for various pixel points with the welding parts arranged as shown in FIG. 6 and PPA checked for corresponding pixel points with the welding parts arranged as shown in FIG. 5. FIG. 10B more visually illustrates different influences on PPA for the arrangement of the welding parts shown in FIG. 6 and the arrangement of the welding parts shown in FIG. 5.

It will be understood by those skilled in the art that in the above examples, the welding parts are provided by taking at most four welding parts being provided on one side of the mask sheet as an example, and it is of course possible to provide more or less welding parts according to practical requirements. In addition, although in the above examples, a welding part is provide with respect to each howling sheet on one side of each mask sheet, it is of course possible to provide more welding parts according to practical requirements, as long as the desired PPA offset can be achieved.

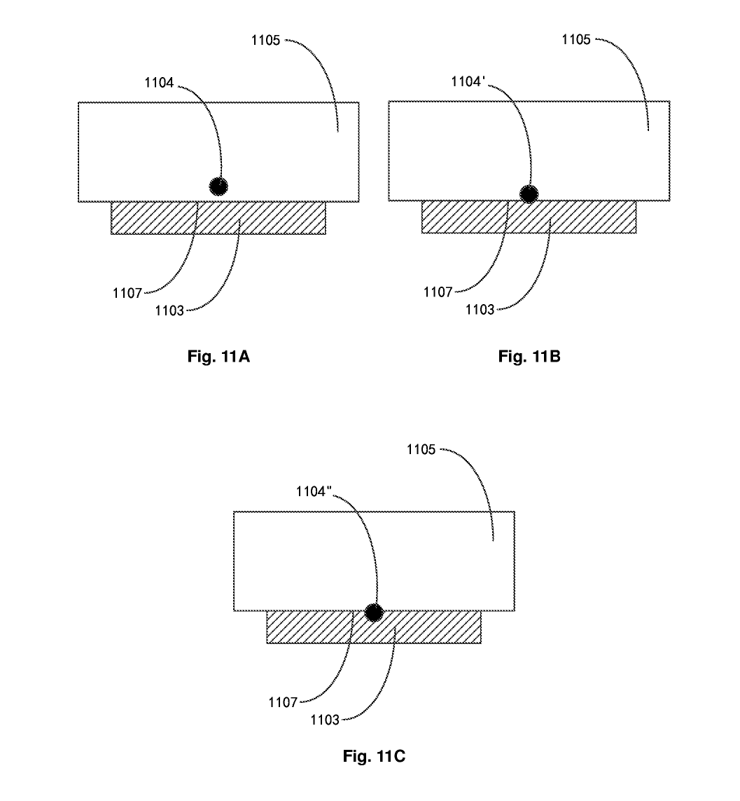

According to the embodiments of the present disclosure, it is also possible to realize desired PPA correction according to a combination of positions and welding energies of the welding parts. FIGS. 11A to 11C illustrate diagrams of positions of welding parts according to an embodiment of the present disclosure. As shown in FIG. 11A, 1107 represents a boundary between a mask sheet 1105 and a howling sheet 1103. As shown in FIG. 11A, a distance between a central point of a welding part 1104 and the boundary 1107 in FIG. 11A is long, for example, 500 μm, in which case the influence of the welding part 1104 on PPA is relatively small, that is, an amount of a PPA offset which can be achieved is small. As shown in FIG. 11B, 1107 represents the boundary between the mask sheet 1105 and the howling sheet 1103. Compared with the case in FIG. 11A, a distance between a central point of a welding part 1104′ and the boundary 1107 in FIG. 11B is shorter, for example, 200 μm, in which case the influence of the welding part 1104′ on the PPA is larger than that in the case of FIG. 11A, that is, an amount of a PPA offset which can be achieved is larger. As shown in FIG. 11C, 1107 represents the boundary between the mask sheet 1105 and the howling sheet 1103. Compared with the case in FIG. 11B, a distance between a central point of a welding part 1104″ and the boundary 1107 in FIG. 11C is shorter, for example, −150 μm, in which case the influence of the welding part 1104″ on the PPA is larger than that in the case of FIG. 11B, that is, an amount of a PPA offset which can be achieved is larger. It should be noted here that the distance between the central point of the welding part 1104″ and the boundary 1107 in FIG. 11C may be a negative value, which indicates that the central point of the welding part 1104″ is outside the mask sheet 1105.

In addition, according to the embodiments of the present disclosure, the larger the welding energies (for example, the welding power) for the welding parts, the larger the amount of the PPA offset, and the smaller the welding power, the smaller the amount of the PPA offset. The arrangement scheme of the welding parts, i.e., at least one of a number of the welding parts, welding positions of the welding parts and corresponding welding energies for the welding parts (in other words, different combinations of the number of the welding parts, the welding positions of the welding parts and the welding energy for the welding parts) can be set by those skilled in the art according to practical requirements to achieve the desired amount of the PPA offset.

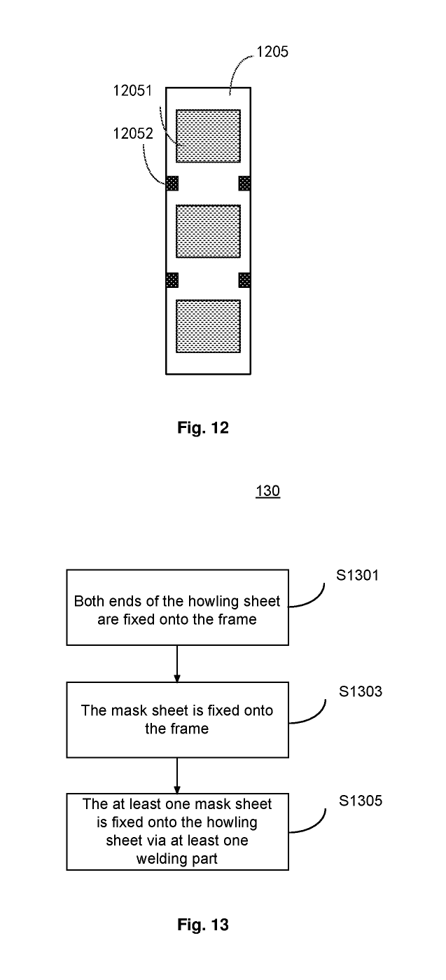

According to the embodiments of the present disclosure, when a welding part is provided between the mask sheet and the howling sheet, assembly of the mask plate may be influenced by a height of the welding part. At least one recessed area, i.e., a half-etching area, for forming a welding part may be formed at a corresponding position on the mask sheet by etching. FIG. 12 illustrates a diagram of positions of recessed areas according to an embodiment of the present disclosure. It should be noted that the example of FIG. 12 corresponds to the arrangement of the welding parts of the mask plate shown in FIG. 3, and each mask sheet 1205 corresponds to a plurality of welding parts, wherein there are equal number of welding parts on opposite sides of the mask sheet 1205 in an extension direction of the howling sheet. As shown in FIG. 12, a mask sheet 1205 is shown as an example. The mask sheet 1205 comprises a plurality of mask units 12051 and recessed areas 12052 corresponding to various welding parts in FIG. 3. It will be understood by those skilled in the art that the recessed areas may be provided in one-to-one correspondence with various welding parts. Of course, the recessed areas may be arranged uniformly, and welding is performed at positions of required recessed areas rather than all the recessed areas according to practical requirements.

According to the embodiments of the present disclosure, there is also proposed a method for assembling a mask plate according to an embodiment of the present disclosure. FIG. 13 illustrates a flowchart of the method according to the embodiment of the present disclosure. It should be noted that sequence numbers of various steps in the following method are used only as representations of the steps for convenience of description and should not be considered as representing an execution order of the respective steps. Unless explicitly stated otherwise, the method does not need to be performed in exactly the order shown. As described above, the mask plate according to an embodiment of the present disclosure may comprise a frame, a howling sheet, and at least one mask sheet. As shown in FIG. 13, the method 130 according to the embodiment of the present disclosure may comprise the following steps.

In step S1301, both ends of the howling sheet are fixed onto the frame.

In step S1303, the mask sheet is fixed onto the frame.

In step S1305, the at least one mask sheet is fixed onto the howling sheet via at least one welding part.

The method according to the embodiment of the present disclosure may further comprise: forming at least one recessed area for forming the welding parts on the mask sheet by etching.

The method according to the embodiment of the present disclosure may further comprise:

measuring Pixel Position Accuracy (PPA) of a plurality of predetermined pixel points; and

determining an arrangement scheme of the welding parts (the recessed areas) according to the measured PPA.

In an embodiment, determining an arrangement scheme of the welding parts according to the measured PPA may comprise: determining a number of the welding parts and which end portions of an overlapped region between the mask sheet and the howling sheet the welding parts are to be located in an extension direction of the howling sheet according to the measured PPA (i.e., roughly determining positions of the welding parts).

In the embodiment, determining an arrangement scheme of the welding parts according to the measured PPA may further comprise: determining positions of the welding parts in the end portions of the overlapped region and/or welding energy for the welding parts. Determining positions of the welding parts in the end portions of the overlapped region is finer determination of the positions of the welding parts, for example, determining distances of the welding parts from a boundary of the mask sheet with respect to the end portion where the welding parts are located.

In another embodiment, determining an arrangement scheme of the welding parts according to the measured PPA may comprise determining at least one of a number of the welding parts, positions of the welding parts and corresponding welding energy for the welding parts according to the measured PPA.

According to the embodiments of the present disclosure, the at least one mask sheet is fixed onto the howling sheet via at least one welding part. By setting at least one of a number of the welding parts, positions of the welding parts, and corresponding welding energy for the welding parts, PPA in various variation trends can be corrected according to practical requirements, thereby improving the yield of the mask plate.

Although the present disclosure has been particularly shown and described with reference to exemplary embodiments of the present disclosure, it will be understood by those of ordinary skill in the art that various changes can be made to these embodiments in form and detail without departing from the spirit and scope of the present disclosure as defined by the appended claims.

I/We claim:

1. A mask plate, comprising:
a frame;
a howling sheet located on the frame; and
at least one mask sheet fixed onto the frame and supported by the howling sheet,
wherein the at least one mask sheet is fixed onto the howling sheet via at least one welding part.

2. The mask plate according to claim 1, wherein the at least one welding part comprises a plurality of welding parts, and the plurality of welding parts are located in end portions of an overlapped region between the mask sheet and the howling sheet in an extension direction of the howling sheet.

3. The mask plate according to claim 2, wherein there are equal numbers of welding parts in both end portions of the overlapped region.

4. The mask plate according to claim 2, wherein there are different numbers of welding parts in both end portions of the overlapped region.

5. The mask plate according to claim 4, wherein the at least one welding part is located in the same end portion of the overlapped region.

6. The mask plate according to claim 1, wherein the mask sheet has recessed areas formed by etching, and the welding parts are formed on the recessed areas.

7. The mask plate according to claim 2, wherein the mask sheet has recessed areas formed by etching, and the welding parts are formed on the recessed areas.

8. The mask plate according to claim 3, wherein the mask sheet has recessed areas formed by etching, and the welding parts are formed on the recessed areas.

9. The mask plate according to claim 4, wherein the mask sheet has recessed areas formed by etching, and the welding parts are formed on the recessed areas.

10. The mask plate according to claim 5, wherein the mask sheet has recessed areas formed by etching, and the welding parts are formed on the recessed areas.

11. A method for assembling a mask plate comprising a frame, a howling sheet and at least one mask sheet, the method comprising:
fixing both ends of the howling sheet onto the frame;
fixing the at least one mask sheet onto the frame; and
fixing the at least one mask sheet onto the howling sheet via at least one welding part.

12. The method according to claim 11, further comprising:
forming at least one recessed area for forming the at least one welding part on the mask sheet by etching.

13. The method according to claim 11, wherein the at least one welding part comprises a plurality of welding parts, and further comprising:
measuring Pixel Position Accuracy (PPA) of each of a plurality of predetermined pixel points; and
determining an arrangement scheme of the welding parts according to the measured PPA.

14. The method according to claim 13, wherein determining an arrangement scheme of the welding parts according to the measured PPA comprises:
determining a number of the welding parts and which end portions of an overlapped region between the mask sheet and the howling sheet the welding parts are to be located in an extension direction of the howling sheet according to the measured PPA.

15. The method according to claim 14, wherein determining an arrangement scheme of the welding parts according to the measured PPA further comprises:
determining positions of the welding parts in the end portions of the overlapped region and/or welding energies for the welding parts.

16. The method according to claim 12, wherein the at least one welding part comprises a plurality of welding parts, and further comprising:
measuring Pixel Position Accuracy (PPA) of each of a plurality of predetermined pixel points; and
determining an arrangement scheme of the welding parts according to the measured PPA.

17. The method according to claim 16, wherein determining an arrangement scheme of the welding parts according to the measured PPA comprises:
determining a number of the welding parts and which end portions of an overlapped region between the mask sheet and the howling sheet the welding parts are to be located in an extension direction of the howling sheet according to the measured PPA.

18. The method according to claim 17, wherein determining an arrangement scheme of the welding parts according to the measured PPA further comprises:
determining positions of the welding parts in the end portions of the overlapped region and/or welding energies for the welding parts.
